(19) United States
(12) Patent Application Publication
(10) Pub. No.: US 2007/0290205 A1
(43) Pub. Date: Dec. 20, 2007

(54) DUAL-CHANNEL THIN FILM TRANSISTOR

(76) Inventors: Chin-Sheng Chen, I-Lan Hsien (TW); Chih-Hung Liu, Tao-Yuan Hsien (TW); Chien-Hsing Hung, Tao-Yuan Hsien (TW); Kun-Yuan Huang, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/423,961

(22) Filed: Jun. 14, 2006

(51) Int. Cl. H01L 29/04

(52) U.S. Cl. 257/59

(57) ABSTRACT

A dual-channel thin film transistor is applied to a thin film transistor liquid crystal display. It includes a substrate, a gate electrode, a source, and a drain. The drain further includes two drain electrodes. The two drain electrodes form the dual-channel with the source. A channel layer is between the source, the drain and the gate electrode.

### BACKGROUND OF THE INVENTION

1. Field of the Invention

The present invention relates to a TFT, and more particularly, to a TFT having dual-channel.

2. Description of the Prior Art

In general, thin film transistor liquid crystal displays (TFT LCDs) comprise thin-film transistor array substrates, a color filter substrate (CF substrate), and a liquid crystal layer between two substrates. The TFT array substrate has a plurality of TFTs. The TFTs are deposited in matrix. Each TFT has a pixel electrode, and the pixel electrode connects electrically with the TFT to form a pixel unit. The TFT is a switch of the liquid crystal display unit. Each TFT is formed a gate, a channel layer, and source/drain on the insulating substrate sequentially.

Please refer to FIG. 1. FIG. 1 is a diagram of a TFT structure according to the prior art. As mentioned previously, the prior art LCD has a plurality of ordered pixel units (not shown). Each pixel unit includes a pixel unit 111 and a TFT 100. Wherein TFT 100 includes a substrate (not shown), a gate 106, a channel layer 112, and a source/drain 108/110 layer. And, the gate 106 is connected electrically with the scan line 105. The source/drain 108/110 are connected electrically with the data line 102 and the pixel electrode 111.

However, etching processes during the TFT manufacture including the back channel etching (BCE) process, and the channel between the source and the drain process will leave some metal particles or conductive pollutions even after a following washing process. This causes a point defect to be produced in the channel of the TFT. The connection shorts between the source and the drain in the channel, and the switch effect of the TFT is destroyed.

Please refer to FIGS. 2 and 3. FIGS. 2 and 3 are diagrams of a point defect of the TFT channel according to the prior art. FIGS. 2 and 3 show the same structure as in FIG. 1, except FIGS. 2 and 3 show a point defect 202 in the channel 114 between the source 108 and the drain 110. This point defect 202 means the channel 114 is destroyed and the TFT 100 cannot turn on or off to drive the pixel unit (not shown). In the prior art, there are two ways to repair such a point defect of the TFT channel. The first method is shown in FIG. 2. A wire 204 using silver paste connects the drain 110 and the data line 102. Therefore, no matter whether the voltage signal is passed into the scan line (not shown) or not, the pixel unit (not shown) of TFT 100 still has a potential difference between the pixel electrode and the common electrode. The liquid crystals of the pixel unit are deflected by the whole data signal of the data line 102, so the pixel unit is a bright dot. The other method of repairing the point defect in the TFT channel is shown in FIG. 3. A laser cuts part of the drain 110 to form a gap 206. The drain 110 cannot connect electrically to the source 108. Thus, the corresponding pixel unit (not shown) cannot be controlled by the data signal of the data line 102. The potential difference cannot be produced and the liquid crystals cannot be deflected. The pixel unit is maintained as a dark dot.

The prior art compensates for point defects by connecting the drain and the data line to make the pixel unit a bright dot, or by cutting the drain to make the pixel unit a dark dot. No matter what kind of repairing means are used, the pixel unit cannot be driven in a normal way. Consequently, how to invent a point defect repairing method to maintain the switch effect of the TFT in the pixel unit is an important issue.

### SUMMARY OF THE INVENTION

The present invention provides a TFT having dual-channels to solve the above-mentioned problem.

An embodiment of the present invention provides a dual-channel thin film transistor applied to a thin film transistor liquid crystal display. It includes a gate electrode, a source, and a drain. The drain further includes two drain electrodes. The two drain electrodes form dual-channels with the source. A channel layer is between the source, the drain and the gate electrode.

The TFT has two drain electrodes in the present invention, having independent channels with the source, thereby producing a dual-channel transistor structure. Therefore, if one channel is destroyed by a point defect, the drain electrode can be cut to prevent the abnormal channel from working, and the channel that is in good condition can still work. Therefore the TFT in the pixel unit still maintains a normal switch effect.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a TFT structure according to the prior art.

FIGS. 2 and 3 are diagrams of a point defect of the TFT channel according to the prior art.

FIG. 4 is a diagram of a TFT structure according to an embodiment of the present invention.

FIG. 5 is a diagram of repairing a point defect of the TFT channel according to the present invention.

FIG. 6 is a diagram of a TFT structure according to another embodiment of the present invention.

FIG. 7 is a diagram of repairing a point defect of the TFT channel according to the present invention.

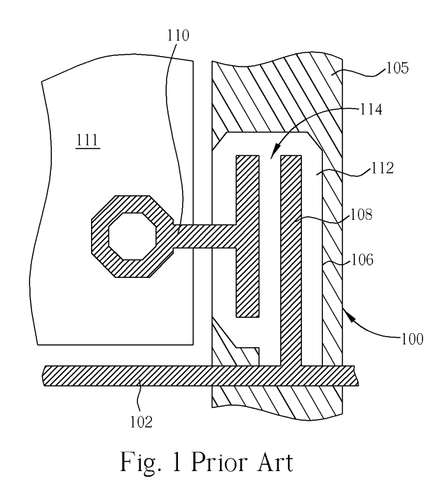

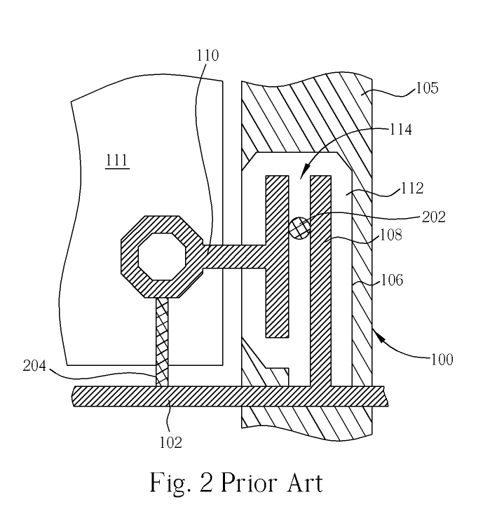

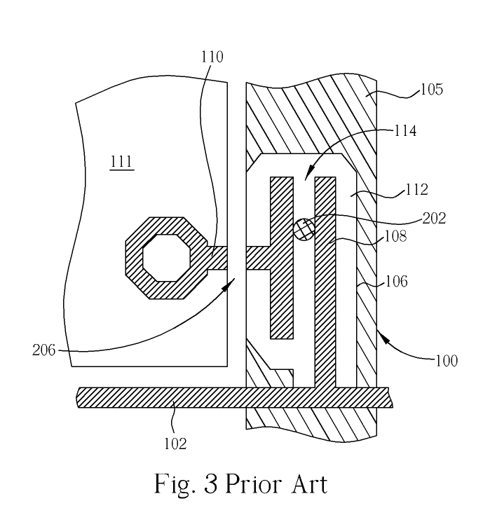

### DETAILED DESCRIPTION

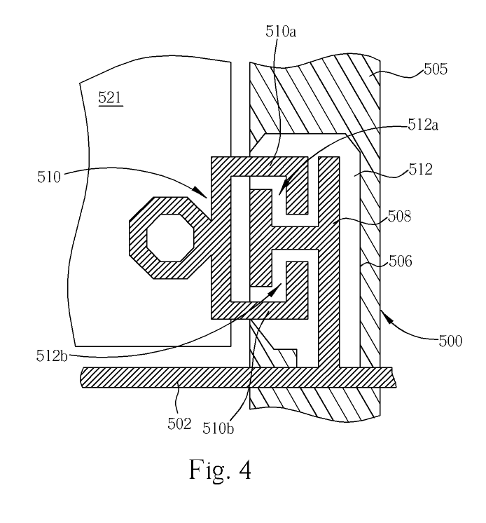

Please refer to FIG. 4. FIG. 4 is a diagram of a TFT structure according to an embodiment of the present invention. The present invention applies to a display array area and the peripheral area of a thin film transistor liquid crystal display (TFT-LCD) or an organic light emitting diode (OLED) display. The embodiment takes a TFT LCD as an example. As FIG. 4 shows, the TFT LCD has a plurality of ordered pixel units (not shown). Each pixel unit has a TFT 500 to control the deflection of the liquid crystals in the corresponding pixel unit (not shown). Each TFT 500 has a substrate (not shown), a gate 506 on the substrate, a gate electrode insulator (not shown) on the gate and the substrate, and a channel 512 on the gate electrode insulator and on the gate 506. Otherwise, each TFT 500 has a gate electrode 506 connected to a scan line 505, an I structure source 508, and a C structure drain 510. The C structure drain 510 comprises two L structure drain electrodes 510a, and 510b. The I structure source 508 is in the hole of the C structure drain 510. The two L structure drain electrodes 510a, 510b form channels 512a, 512b in the channel layer 512. There is a gate electrode insulator (not shown) between the gate electrode 506 and the channel layer 512. Wherein the gate 508 is connected electrically with the gate line 502, and the drain electrodes 510a, 510b are connected electrically with the pixel electrode 521. The gate electrode 506 of the pixel unit (not shown) is turned on by the voltage signal of the scan line 505. Then, the channel layer 512 between the source 508, and the drain electrodes 510a, 510b forms channels 512a, 512b through inversion of the threshold voltage, and the source 508 connects electrically to the drain electrodes 510a, and 510b. The data signal of the data line 502 passes into the drain electrodes 510a, 510b through the source 508 and causes a potential difference across the pixel electrode 521 connecting to the drain 510 and the common electrodes (not shown). Therefore, the liquid crystals of the pixel unit (not shown) are deflected.

As detailed above, etching processes during the TFT manufacture including the back channel etching (BCE) process, and the channel between the source and the drain process will leave some metal particles or conductive pollutions even after a following washing process. A point defect is therefore produced in the channel of the TFT. The source shorts with the drain in the channel, and the switch effect of the TFT is destroyed.

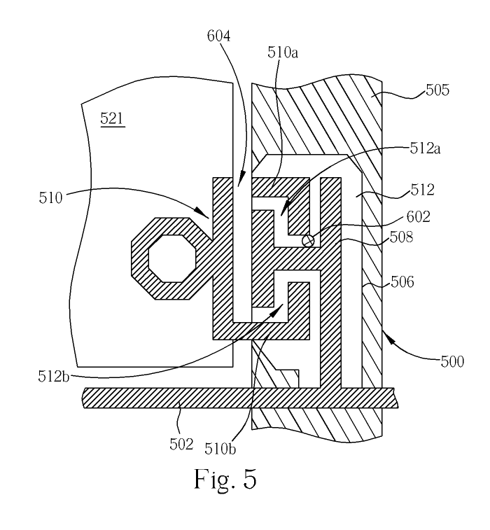

Please refer to FIG. 5. FIG. 5 is a diagram of repairing a point defect of the TFT channel according to the present invention. FIG. 5 shows the same structure as in FIG. 4, and details the repairing method of the point defect in the TFT 500 according to the present invention. As FIG. 5 shows, the point defect 602 is between the drain electrode 510a and the source 508, causing the channel 512a between the drain electrode 510a and the source 508 to be destroyed. A laser cuts part of the drain electrode 510a to form a gap 604. The drain electrode 510a cannot connect electrically to the pixel electrode 521. Thus, the pixel electrode 521 cannot pass the data signal through the drain electrode 510a. The channel 512b between the drain electrode 510b and the source 508 is still in good condition, however. When the gate electrode 506 of the pixel unit (not shown) is turned on by the voltage signal of the scan line 505, the channel layer 512 between the drain electrode 510b and the source 508 forms a channel 512b through the inversion of the threshold voltage. The source 508 connects electrically to the drain electrode 510b. Then, the scan signal of the data line 502 is passed into the pixel electrode 512 connected electrically to the drain 510 by the drain electrode 510b. Then, the potential difference between the pixel electrode 512 and the corresponding common electrodes (not shown) is produced, and the liquid crystals are deflected. This means the pixel unit having the point defect 602 can still maintain the switch effect after the repair.

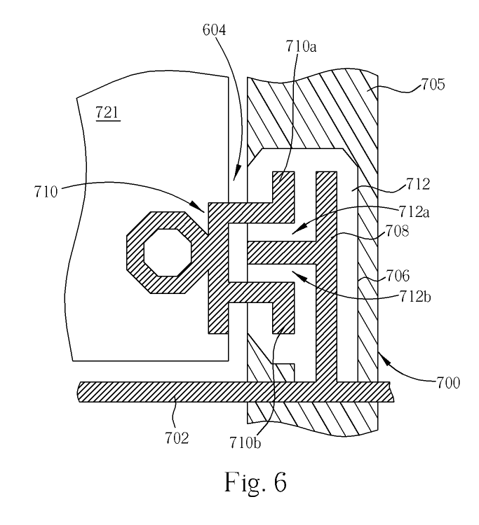

Please refer to FIG. 6. FIG. 6 is a diagram of a TFT structure according to another embodiment of the present invention. The TFT in FIG. 6 is similar to the TFT in FIG. 4. Both diagrams show the structure of the TFT 700 in the TFT LCD. The TFT 700 has a substrate (not shown), a gate 706 on the substrate, a gate electrode insulator (not shown) on the gate and the substrate, and a channel 712 on the gate electrode insulator and on the gate 706. Otherwise, each TFT 700 comprises a gate electrode 706 connected to a scan line 705, a T structure source 708, and a π structure drain 710. The π structure drain 710 comprises two L structure drain electrodes 710a, and 710b. The T structure source 708 is between the two L structure drain electrodes 710a, 710b. The two L structure drain electrodes 710a, 510b form channels 712a, 712b in the channel layer 712. There is a gate electrode insulator (not shown) between the gate electrode 706 and the channel layer 712. The gate electrode 706 of the pixel unit (not shown) is turned on by the voltage signal of the scan line 705. Then, the channel layer 712 between the source 708, the drain electrodes 710a, 710b forms channels 712a, 712b through inversion of the threshold voltage, and the source 708 connects electrically to the drain electrodes 710a, 710b. The data signal of the data line 702 passes into the drain electrodes 710a, 710b by the source 708 and causes a potential difference across the pixel electrode 721 connecting to the drain 710 and the common electrodes (not shown). The liquid crystals of the pixel unit (not shown) are deflected.

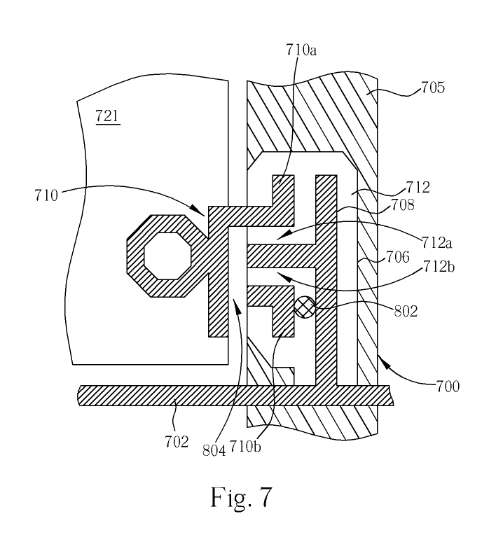

Please refer to FIG. 7. FIG. 7 is a diagram of repairing a point defect of the TFT channel according to the present invention. FIG. 7 details the repairing method of the point defect in the TFT 700. As FIG. 7 shows, the point defect 802 is in a channel 712b. A laser cuts part of the drain electrode 710b to form a gap 804, meaning the drain electrode 710b cannot connect electrically to the pixel electrode 721. Thus, the pixel electrode 721 cannot pass the data signal through the drain electrode 710b. The channel 712a between the drain electrode 710a and the source 708 is still in good condition, however. When the gate electrode 706 of the pixel unit (not shown) is turned on by the voltage signal of the scan line 705, the channel layer 712 between the drain electrode 710a and the source 708 forms the channel 712a through the inversion of the threshold voltage. The source 708 connects electrically to the drain electrode 710a. Then, the scan signal of the data line 702 is passed into the pixel electrode 721 connected electrically to the drain 710 by the drain electrode 710a. A potential difference between the pixel electrode 721 and the corresponding common electrodes (not shown) is then produced, and the liquid crystals are deflected. This means the pixel unit having the point defect 802 can still maintain the switch effect after the repair.

Please note that the present invention is not limited to the two drain electrodes of the above-mentioned two embodiments. The TFT can form a plurality of channels according to the design rule and still satisfy the manufacture conditions and circuit design. The disposition of the source and the drain electrode in the present invention can also be changed, and is not limited to the above-mentioned disposition. Moreover, because the TFT in the present invention has dual channels, the repairing effect is improved, and the channel width increased.

The TFT has two drain electrodes in the present invention. The two drain electrodes have independent channels with the source, so the dual-channel transistor structure is produced. Therefore, when one channel is destroyed by the point defect, the drain electrode can be cut to stop the abnormal channel. The channel that is in good condition can still work, and the TFT in the pixel unit still maintains a normal switch effect.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A dual-channel thin film transistor comprising:
a substrate;
a gate electrode on the substrate;
a gate electrode insulator on the gate and the substrate;
a channel layer on the gate electrode insulator layer and on the gate; and
a source and a drain, the drain comprising two drain electrodes, wherein the drain electrodes form the dual-channel with the source.

2. The dual-channel thin film transistor of claim 1, is applied to an organic light emitting diode (OLED) display.

3. The dual-channel thin film transistor of claim 1, wherein the TFT is applied to a thin film transistor liquid crystal display (TFT LCD).

4. The dual-channel thin film transistor of claim 3, wherein the TFT LCD comprises a plurality of pixel units.

5. The dual-channel thin film transistor of claim 4, wherein the TFT LCD comprises liquid crystal in each pixel units.

6. The dual-channel thin film transistor of claim 3, wherein the source connects electrically to a data line of the TFT LCD.

7. The dual-channel thin film transistor of claim 3, wherein the gate connects electrically to a scan line of the TFT LCD.

8. The dual-channel thin film transistor of claim 1, wherein the drain connects electrically to a pixel electrode of the TFT LCD.

9. The dual-channel thin film transistor of claim 1, wherein the source has a structure I.

10. The dual-channel thin film transistor of claim 9, wherein the drain has a structure C.

11. The dual-channel thin film transistor of claim 10, wherein the structure of I is in the hole of the structure of C.

12. The dual-channel thin film transistor of claim 11, wherein both drain electrodes have structures L to form the structure C of the drain.

13. The dual-channel thin film transistor of claim 1, wherein the source has a structure T.

14. The dual-channel thin film transistor of claim 13, wherein the drain has a structure π.

15. The dual-channel thin film transistor of claim 14, wherein both drain electrodes have structures L to form the structure π of the drain.
